(19) United States
(12) Patent Application Publication
(10) Pub. No.: US 2023/0309245 A1
(43) Pub. Date: Sep. 28, 2023

(54) Optical sensor package assembly

(71) Applicant: Luxsentek Microelectronics Corp., New Taipei City (TW)

(72) Inventors: Sheng-Cheng Lee, New Taipei City (TW); Wen-Sheng Lin, New Taipei City (TW); Chao-Yang Hsiao, New Taipei City (TW); Chih-Wei Lin, New Taipei City (TW); Chen-Hua Hsi, New Taipei City (TW); Yueh-Hung Ho, New Taipei City (TW)

(21) Appl. No.: 18/188,186

(22) Filed: Mar. 22, 2023

(30) Foreign Application Priority Data
Mar. 22, 2022 (TW) 111110482

(51) Int. Cl. H05K 5/00; H05K 1/18; H05K 1/11

(52) U.S. Cl. CPC H05K 5/0091; H05K 1/181; H05K 1/11; H05K 2201/10106; H05K 2201/10121

(57) ABSTRACT

The present invention provides an optical sensor package assembly. The light shield is arranged in the groove of a package housing above the photosensitive chip. The connection wires between the substrate, the light emitting unit and the photosensitive chip can be printed or disposed on the surface of the substrate. Further, a distance between the photosensitive element and the chip edge is designed to reduce or avoid side leakage interference.

### BACKGROUND OF THE INVENTION

### 1. Field of the Invention

The present invention relates a photosensor and in particular that has a super small packaging structure.

### 2. Description of the Prior Art

Proximity sensors (PS) are widely used in smart phones or wearable devices for sensing an approaching object. A PS irradiates an object and collects the reflected light intensity to calculate the distance to the object. It is necessary to dispose an opaque member between the light-emitting element and the photosensitive element to avoid or reduce the cross-talk (CT). The opaque member affects the wiring and the miniaturization of package size.

### SUMMARY OF THE INVENTION

For an optical sensor package assembly of this invention, a groove is formed on the package housing above the photosensitive chip and the groove is filled an opaque material as a light shielding member. The light shielding member does not occupy space of the substrate and affect the wiring of the substrate. As a result, the package size can be further miniaturized and the package height is thinner. The present invention can be applied to small wearable devices such as watches and earphones.

Further, the photosensitive element or photodiode is positioned at the corner with a distance to the side of the chip. The distance can be used to reduce the side leakage interference.

### BRIEF DESCRIPTION OF THE DRAWINGS

FIG. 1 is a three-dimensional perspective view of the optical sensor package assembly of the present invention.

FIG. 2 is a side perspective view of the optical sensor package assembly of the present invention.

FIG. 3 is a three-dimensional perspective view of an optical sensor package assembly according to another embodiment of the present invention.

FIG. 4 is a light waveform diagram of the field intensity at different view angle from the axis vertical with the surface of the optical sensor package assembly according to an embodiment.

FIG. 5 is a light waveform diagram of the field intensity at different view angle vertical with the surface of the optical sensor package assembly according to another embodiment of the present invention.

### DESCRIPTION OF THE PREFERRED EMBODIMENTS

The following embodiments and the diagrams are intended to illustrate the spirit of the present invention to person having ordinary skilled in the art to be clearly understand the technology of the present invention, but are not intended to limit its scope, as defined by the claims. It is emphasized that the diagrams are for illustration only, and do not represent the actual size or quantity of components, and some details may not be fully drawn for the sake of simplicity of the diagrams.

In an optical sensor package assembly of the present invention, a light shielding member formed on its package housing above a photosensitive structure. The bonding wires are arranged between a light-emitting unit and a photosensitive element of the photosensor, called a reverse bonding. The shielding member can reduce the optical crosstalk and the height of the package. The reverse bonding can reduce the size of the package. The shielding member is above the chip, that can reduce the package height. As a result, the package can be further miniaturized. The invention provides a more flexible design when being applied to a wearable device such as an earphone or a smart watch.

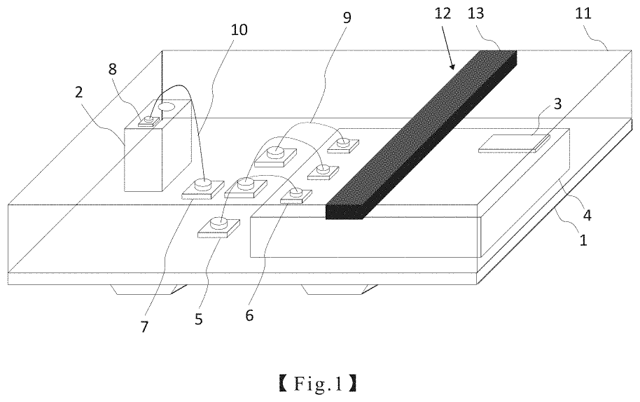

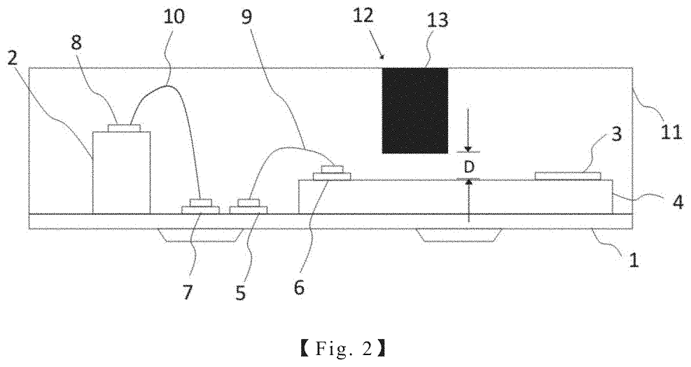

FIG. 1 and FIG. 2 are a three-dimensional perspective view and a side perspective view of the optical sensor packaging assembly of the present invention. A light-emitting unit 2 and a photosensitive structure are arranged on a substrate 1. The photosensitive structure includes a photosensitive element 3 (such as a photodiode). The photosensitive structure can be a chip 4 and the photosensitive element 3 is integrated in the chip 4. In one embodiment, the photosensitive element 3 is embedded on the surface of the chip 4.

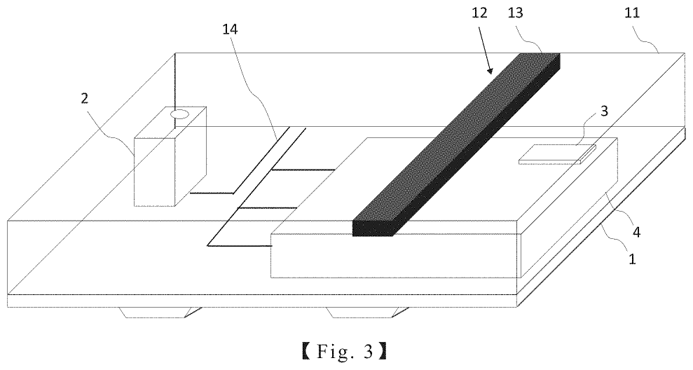

The integrated circuit chip 4 is provided with a plurality of second bonding pads 6. A plurality of first bonding pads 5 and at least one third bonding pad 7 are arranged on the substrate 1 between the light-emitting unit 2 and the photosensitive structure. The first bonding wire 9 connects the photosensitive structure to the substrate 1 via the first bonding pads 5 and the second bonding pads 6. The second bonding wire 10 connects the light-emitting unit 2 to the substrate 1 via the third bonding pad 7. In another embodiment shown as FIG. 3, a circuit wiring 14 is printed on surface of the substrate 1. The circuit wiring 14 connects the light-emitting unit 2 and the chip 4 to the substrate 1.

There is no light shielding member above the substrate 1. The bonding wires, regardless of through bonding pad or printed wiring, can be made on the surface of the substrate 1 between the light-emitting unit and the photosensitive chip. It is called a reverse bonding and that can simplify the manufacturing very much further reduce the package size and the package height i.e., the package is further miniaturized.

The substrate 1, the light emitting unit 2, the photosensitive structure, all the bonding wires and/or all the bonding pads are covered with a transparent package housing 11. A groove 12 is formed in the transparent package housing 11 and located above the photosensitive structure, the chip 4 in the embodiment, between the light emitting unit 2 and the photosensitive element 3. The groove 12 extends toward the integrated circuit chip 4 and is filled with an opaque material 13. A distance D of the base of groove 12 to the chip 4 is in the range 50 μm to 100 μm. The width of the groove 12 is 150 μm to 200 μm and the depth of the groove 12 is 20 μm to 50 μm.

Preferably, the light-emitting unit 2 is higher than the chip 4. The light-emitting unit 2 is lower than the top of the groove 12 and higher than the base of the groove 12, and as a result, the sensed light from the light-emitting unit 2 is reduced or avoided. The groove 12 is arranged close to the photosensitive element 3. A distance of the groove 12 to the photosensitive element 3 is in the range 20 μm to 50 μm. This kind of design can reduce the crosstalk interference and the height of the package.

The material of transparent package 11 is low molecular weight epoxy resin with light refractive index of 1.55 to 1.65. Opaque material 13 is silicon, metal, epoxy resin, resin and silicone rubber mix glue or acrylic glue, or a combination thereof.

The light-emitting unit 2 can be a vertical-cavity surface-emitting laser (VCSEL) or a laser diode. It is noted that the emitting light has a small beam divergence to reduce the crosstalk interference.

In another embodiment, the substrate 1 can optionally be coated with a black layer or material with a high light absorption rate to reduce the reflection, and the interference can be reduced.

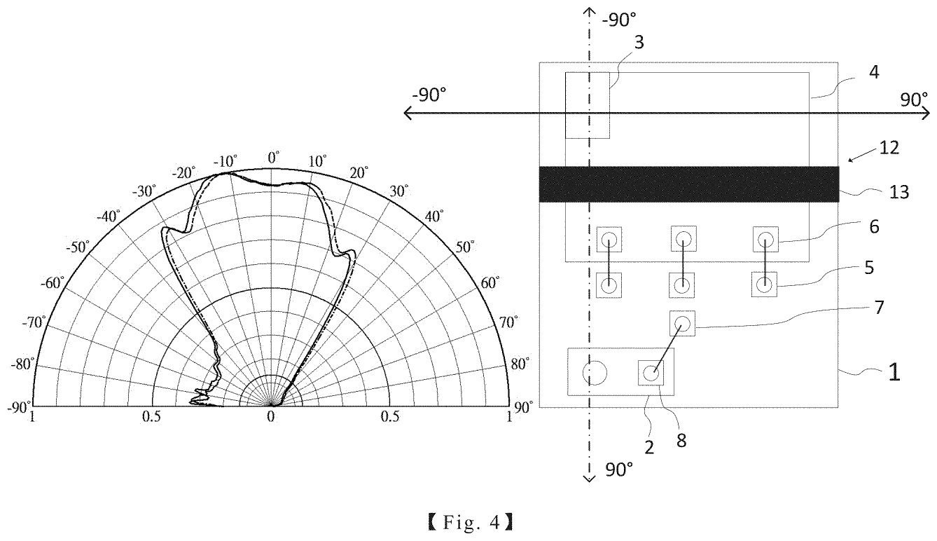

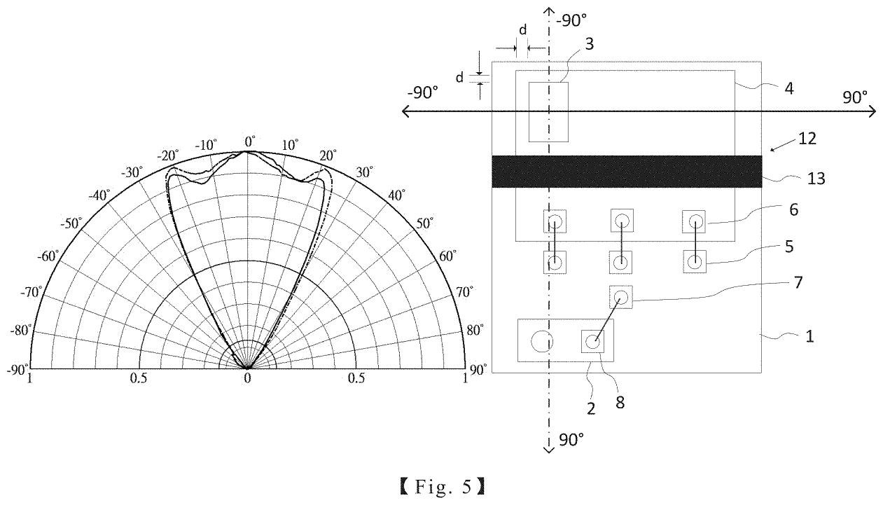

In addition, FIG. 4 and FIG. 5 are field intensity variation diagrams at different view angle with Z-axis for different distances, which are the distance of photosensitive element to the sides of the chip. Z-axis is vertical with the surface of the photosensitive chip, and X-axis and the Y-axis are defined as the parallel orientations of both sides of the photosensitive element adjacent with the chip. The origin is at the center of the photosensitive element. The field intensities along the X-axis (Z-X plane) and Y-axis (Z-Y plane) are measured in the view angle range from −90° to +90°. The field intensity on the Z-X plane is marked in dark gray, and on the Z-Y plane is marked in light gray.

As shown as FIG. 4, the photosensitive element is aligned with both edges of the chip. The normal view angle range (i.e. the angle to sense the proximity object) falls from −38° to +31°, and it is obvious the sensing angle is not symmetrical with respective to the Z-axis. In addition, there exists a larger interference (dotted circles) in the view angle range from −50° to −90° in regardless of the Z-X plane or the Z-Y plane. The interference should be from the side leakage.

In the embodiment of FIG. 5, the photosensitive element is arranged at location with a distance d from the adjacent both sides of the chip. The distance d is in the range 70 μm to 100 μm. Two distances could be different, but they are the same in this example for simplifying the measurement. The normal sensing angle falls in the range −30° to +30°. It is obvious that the sensing angle become more symmetrical and the side-leakage interference is reduced a lot.

What is claimed is:

1. An optical sensor package assembly, comprising:
a substrate;
a light-emitting unit and a photosensitive chip arranged on the surface of the substrate;
bonding wires disposed on the surface of the substrate between the photosensitive chip and the light-emitting unit, wherein the bonding wires are configured to electrically connect the photosensitive chip, the light-emitting unit and the substrate; and
a transparent package housing covering the substrate, the light-emitting unit, the photosensitive chip and the bonding wires, wherein the photosensitive chip has a photosensitive element, the transparent package housing has a groove above the photosensitive chip, the groove is filled with an opaque material and the light-emitting unit is lower than the top of the groove and higher than the base of the groove to reduce or avoid the cross-talk effect.

2. The optical sensor package assembly according to claim 1, wherein the bonding wires electrically connect the photosensitive chip, the light-emitting unit and the substrate through bonding pads or are printed on the substrate.

3. The optical sensor package assembly according to claim 1, wherein a distance between the base of the groove to the surface of the photosensitive chip is 50 μm to 100 μm.

4. The optical sensor package assembly according to claim 1, wherein the light-emitting unit is a vertical cavity surface emitting laser or a light emitting diode.

5. An optical sensor package assembly, comprising:
a substrate;
a light-emitting unit and a photosensitive chip arranged on the surface of the substrate; and
a transparent package housing covering the substrate, the light-emitting unit and the photosensitive chip, wherein the photosensitive chip has a photosensitive element, the transparent package housing has a groove above the photosensitive chip between the light emitting unit and the photosensitive element, the groove is filled with an opaque material and the photosensitive element is disposed at one corner of the chip with a specific distance to both adjacent sides of the photosensitive chip wherein the distance can be used to reduce or avoid side leakage interferences.

6. The optical sensor package assembly according to claim 5, wherein the specific distance is 70 μm to 100 μm.

7. The optical sensor package assembly according to claim 5, wherein the bonding wires electrically connect the photosensitive chip, the light-emitting unit and the substrate through bonding pads or are printed on the substrate.
